(19) United States
(12) Patent Application Publication
(10) Pub. No.: US 2026/0142656 A1
(43) Pub. Date: May 21, 2026

(54) SWITCH CIRCUIT OPERATING BEYOND COMPONENT WITHSTAND VOLTAGE CONDITION

(71) Applicant: REALTEK SEMICONDUCTOR CORP., HsinChu (TW)

(72) Inventor: Li-Cheng Chu, HsinChu (TW)

(73) Assignee: REALTEK SEMICONDUCTOR CORP., HsinChu (TW)

(21) Appl. No.: 19/366,701

(22) Filed: Oct. 23, 2025

(30) Foreign Application Priority Data
Oct. 25, 2024 (TW) 113140924

(51) Int. Cl. H03K 17/10

(52) U.S. Cl. CPC H03K 17/102; H03K 2217/0054

(57) ABSTRACT

A switch circuit operating beyond a component withstand voltage condition includes a bias circuit, at least one first transistor, a plurality of second transistors, and a third transistor. The bias circuit includes a plurality of bias components connected in series, and is coupled to a voltage source, to form a plurality of voltage drop nodes through the bias components. The second transistors are connected in series, are coupled to the voltage source, and are coupled to the voltage drop nodes in a one-to-one manner. A first transistor is arranged between any two adjacent second transistors among the second transistors. The third transistor is connected in series with the second transistors to form a switch path. When the third transistor receives a control signal and is turned on, the first transistors are turned off, and the second transistors are turned on, thereby turning on the switch path.

### CROSS-REFERENCE TO RELATED APPLICATION

This non-provisional application claims priority under 35 U.S.C. § 119(a) to Patent Application No. 113140924 filed in Taiwan, R.O.C. on October 25, 2024, the entire contents of which are hereby incorporated by reference.

### BACKGROUND

### Technical Field

The disclosure relates to a switch circuit, and in particular, to a switch circuit operating beyond a component withstand voltage condition.

### Related Art

Recent circuit designs tend to adopt an advanced process. Although an area advantage can be obtained in the design, to apply the design to a conventional analog circuit as a result of a low withstand voltage of an electronic component of the advanced process is difficult. For a 6 nm process, a switch component has a withstand voltage of only 1.8 V, which makes it difficult to apply the switch component to 5 V applications (for example, a USB power supply circuit).

### SUMMARY

In view of the above, an embodiment of the disclosure provides a switch circuit operating beyond a component withstand voltage condition, which includes a bias circuit, at least one first transistor, a plurality of second transistors, and a third transistor. The bias circuit includes a plurality of bias components connected in series with each other, and is coupled to a voltage source, to form a plurality of voltage drop nodes through the bias components. The second transistors are connected in series with each other, are coupled to the voltage source, and are coupled to the voltage drop nodes in a one-to-one manner. A first transistor is arranged between any two adjacent second transistors among the second transistors. The third transistor is connected in series with the second transistors to form a switch path, and is located on a low voltage side of the second transistors. When the third transistor receives a control signal and is turned on, the first transistors are turned off, and the second transistors are turned on, thereby turning on the switch path. When the third transistor receives the control signal and is turned off, the first transistors are turned on, and the second transistors are turned off, thereby turning off the switch path.

According to the switch circuit operating beyond a component withstand voltage condition in some embodiments of the disclosure, the bias components of the bias circuit are adopted to layer in series, so that the component of each layer can perform switch control in a withstand voltage range thereof, to achieve the switch circuit operating at an operating voltage beyond the component withstand voltage condition. In addition, since the control of the switch circuit can be achieved through only a need of feeding a control signal, no situation of a temporary component overvoltage as a result of possible occurrence of a signal delay of a plurality of control signals exists.

### BRIEF DESCRIPTION OF THE DRAWINGS

FIG. 1 is a schematic diagram of a switch circuit operating beyond a component withstand voltage condition according to an embodiment of the disclosure;

FIG. 2 is a schematic diagram of a bias circuit according to another embodiment of the disclosure;

FIG. 3 is a schematic diagram of a bias circuit according to still another embodiment of the disclosure;

FIG. 4 is a schematic diagram of an equivalent switch circuit according to an embodiment of the disclosure;

FIG. 5 is a schematic structural diagram of a third transistor according to an embodiment of the disclosure;

FIG. 6 is a schematic structural diagram of a second transistor according to an embodiment of the disclosure;

FIG. 7 is a schematic diagram of turning on a switch path according to an embodiment of the disclosure;

FIG. 8 is a schematic diagram of turning off a switch path according to an embodiment of the disclosure; and

FIG. 9 is a schematic diagram of applying a switch circuit operating beyond a component withstand voltage condition to a USB protocol according to an embodiment of the disclosure.

### DETAILED DESCRIPTION

A term "couple" used herein means that two or more components are "directly" in physical or electrical contact with each other, or are "indirectly" in physical or electrical contact with each other.

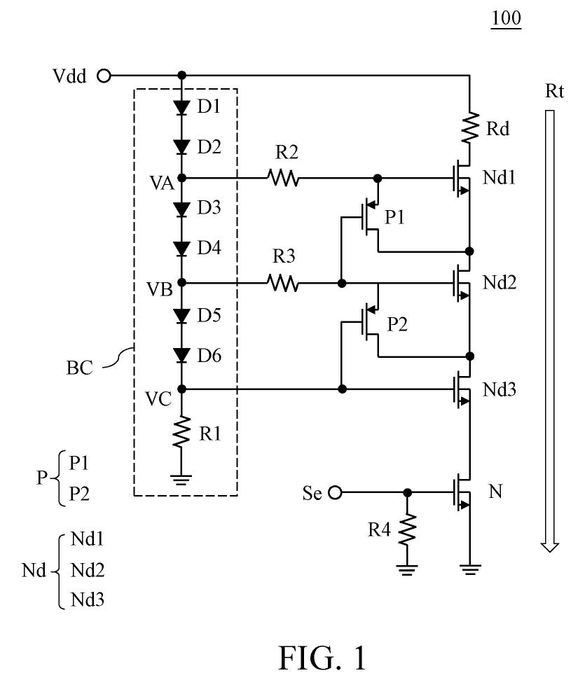

Referring to FIG. 1, FIG. 1 is a schematic diagram of a switch circuit 100 operating beyond a component withstand voltage condition according to an embodiment of the disclosure. The switch circuit 100 operating beyond a component withstand voltage condition includes a bias circuit BC, at least one first transistor P, a plurality of second transistors Nd, and a third transistor N. Herein, a description is provided by using two first transistors P (P1, P2) and three second transistors Nd (Nd1 to Nd3) as an example. The bias circuit BC includes a plurality of bias components connected in series with each other, and is coupled to a voltage source Vdd, to form a plurality of voltage drop nodes VA, VB and VC through the bias components.

Herein, the bias components are achieved by a plurality of diodes D1 to D6 connected in series. The diodes are forward biased with the voltage source Vdd. To be specific, a voltage of the voltage source Vdd is reduced to a voltage of the voltage drop node VA through the diodes D1 and D2, the voltage of the voltage drop node VA is reduced to a voltage of the voltage drop node VB through the diodes D3 and D4, and the voltage of the voltage drop node VB is reduced to a voltage of the voltage drop node VC through the diodes D5 and D6. For example, in an embodiment, the voltage of the voltage source Vdd is 5.5 V, the voltage of the voltage drop node VA is 4 V, the voltage of the voltage drop node VB is 2.4 V, and the voltage of the voltage drop node VC is 0.8 V. Herein, the voltage of each of the voltage drop nodes VA, VB and VC is reduced through two diodes (D1 and D2, D3 and D4, or D5 and D6), but the embodiments of the disclosure are not limited thereto. For example, the quantity may be only one or more than two, which depends on a required voltage value.

In some embodiments, the bias circuit BC further includes a resistor R1, which is coupled between an end terminal of the bias components (which is the voltage drop node VC herein) and a ground terminal, so that a current is formed on the bias circuit BC.

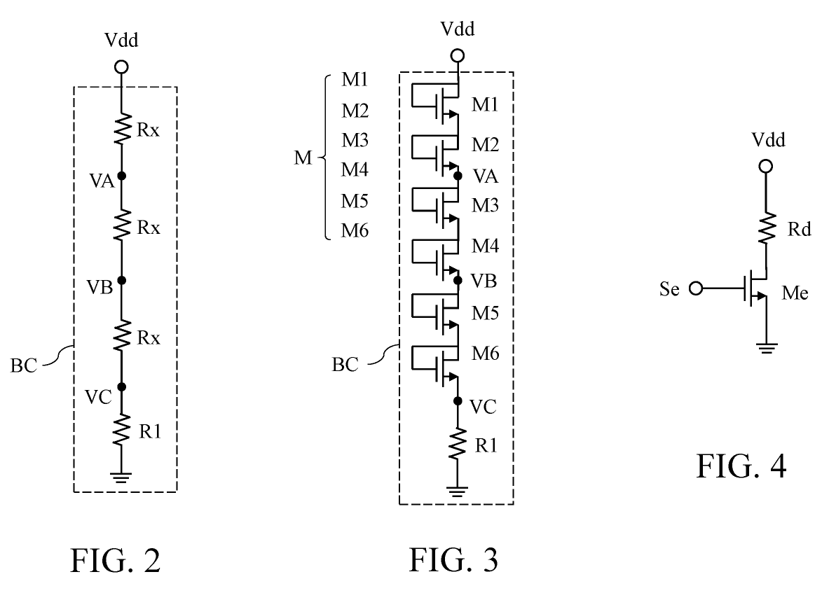

Referring to FIG. 2, FIG. 2 is a schematic diagram of a bias circuit BC according to another embodiment of the disclosure. Herein, bias components are achieved by a plurality of resistors Rx connected in series. Through voltage division, voltage drop nodes VA, VB and VC respectively have voltages after voltage drop.

Referring to FIG. 3, FIG. 3 is a schematic diagram of a bias circuit BC according to still another embodiment of the disclosure. Herein, bias components are achieved by a plurality of fourth transistors M connected in series. Herein, the bias components are achieved by six fourth transistors M (M1 to M6). The fourth transistors M1 to M6 are N-type metal-oxide-semiconductor (MOS) transistors, and each have a fourth gate, a fourth source, and a fourth drain. The fourth drain is coupled to the fourth gate (that is, the fourth drain and the fourth gate form a diode), and is coupled to the fourth source of the fourth transistor M adjacent to the fourth drain. For example, the fourth drain of the fourth transistor M2 is coupled to the fourth gate, and is coupled to the fourth source of the fourth transistor M1. Herein, a voltage of each of the voltage drop nodes VA, VB and VC is reduced through two fourth transistors (M1 and M2, M3 and M4, or M5 and M6), but the embodiments of the disclosure are not limited thereto. For example, the quantity may be only one or more than two, which depends on a required voltage value.

Refer to FIG. 1 again. The second transistors Nd1 to Nd3 are connected in series with each other, are coupled to the voltage source Vdd, and are coupled to the voltage drop nodes VA, VB and VC in a one-to-one manner. A first transistor P is arranged between any two adjacent second transistors among the second transistors Nd1 to Nd3. Herein, the first transistor P1 is arranged between the second transistors Nd1 and Nd2, and the first transistor P2 is arranged between the second transistors Nd2 and Nd3. The third transistor N is connected in series with the second transistors Nd1 to Nd3 to form a switch path Rt, and is located at a low voltage side of the second transistors Nd1 to Nd3. When the third transistor N receives a control signal Se and is turned on, the first transistors P1 and P2 are turned off, and the second transistors Nd1 to Nd3 are turned on, thereby turning on the switch path Rt. When the third transistor N receives the control signal Se and is turned off, the first transistors P1 and P2 are turned on, and the second transistors Nd1 to Nd3 are turned off, thereby turning off the switch path Rt. Therefore, the switch circuit 100 operating beyond a component withstand voltage condition can form an equivalent switch circuit as shown in FIG. 4 (FIG. 4 is a schematic diagram of an equivalent switch circuit according to an embodiment of the disclosure). To be specific, when the switch path Rt is turned on, it is equivalent to that the equivalent switch Me is turned on, and when the switch path Rt is turned off, it is equivalent to that the equivalent switch Me is turned off.

As shown in FIG. 1, each of the first transistors P is a P-type MOS transistor, and has a first gate, a first source, and a first drain. Each of the second transistors Nd is a deep N well (DNW) N-type MOS transistor, and has a second gate, a second source, and a second drain. The second gates of the second transistors Nd are coupled to the corresponding voltage drop nodes VA, VB and VC. To be specific, the second gate of the second transistor Nd1 is coupled to the voltage drop node VA, the second gate of the second transistor Nd2 is coupled to the voltage drop node VB, and the second gate of the second transistor Nd3 is coupled to the voltage drop node VC.

The second gate and the second drain of the second transistor Nd adjacent to the low voltage side to which each first transistor P is coupled are respectively coupled to the first gate and the first drain of the first transistor P. For example, the first gate of the first transistor P1 is coupled to the second gate of the second transistor Nd2, and the first drain of the first transistor P1 is coupled to the second drain of the second transistor Nd2.

The second gate of the second transistor Nd away from the low voltage side (that is, adjacent to a high voltage side) to which each first transistor P is coupled is coupled to the first source of the first transistor P. For example, the first source of the first transistor P1 is coupled to the second gate of the second transistor Nd1.

In any two adjacent second transistors among the second transistors Nd, the second drain of the second transistor Nd adjacent to the low voltage side is coupled to the second source of the second transistor Nd away from the low voltage side (that is, adjacent to the high voltage side). For example, the second drain of the second transistor Nd2 is coupled to the second source of the second transistor Nd1.

The third transistor N is an N-type MOS transistor, and has a third gate, a third source, and a third drain. The third gate is configured to receive the control signal Se. The third source is grounded. The third drain is coupled to the second source of the second transistor Nd3 to which the third transistor N is coupled.

In some embodiments, the voltage drop nodes VA and VB other than the voltage drop node VC on a tail terminal are respectively coupled to the second transistors Nd1 and Nd2 through a resistor R2 and a resistor R3, to generate a voltage difference through the resistors R2 and R3 in some situations, so that different voltages are formed on two ends of each of the resistors R2 and R3.

In some embodiments, the third gate of the third transistor N is coupled to a ground resistor R4. In this way, when the control signal Se is at a low potential, the third gate of the third transistor N can be stably enabled to be maintained at the ground level, to ensure that the third transistor N is maintained in an off state.

In some embodiments, the switch path Rt further includes a pull-down resistor Rd, which is coupled between the voltage source Vdd and the high voltage side of the second transistors Nd. In this way, when the switch path Rt is turned on, the pull-down resistor Rd is grounded, and when the switch path Rt is turned off, no current is formed.

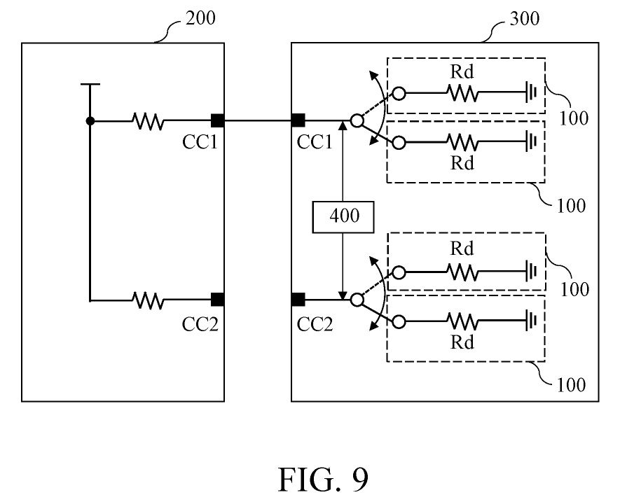

Referring to FIG. 9. FIG. 9 is a schematic diagram of applying a switch circuit 100 operating beyond a component withstand voltage condition to the USB protocol according to an embodiment of the disclosure. A source device terminal 200 and a drain device terminal 300 are coupled through a configuration channel (CC) pin CC1 or CC2 of the USB protocol. In an example, in the drain device terminal 300, each of the CC pins CC1 and CC2 is coupled to a plurality of switch circuits 100 operating beyond a component withstand voltage condition, which have pull-down resistors Rd with different resistance values. Therefore, through on or off of a switch path Rt of each of the switch circuits 100 operating beyond a component withstand voltage condition, voltage division on the CC pins CC1 and CC2 may be changed. Therefore, a CC detector 400 may perform functions such as device detection and communication protocol by measuring voltages on the CC pins CC1 and CC2. Although the above description is provided by using an example in which the switch circuit 100 operating beyond a component withstand voltage condition is arranged in the drain device terminal 300, but the embodiments of the disclosure are not limited thereto. The switch circuit 100 operating beyond a component withstand voltage condition may alternatively be arranged in the source device terminal 200.

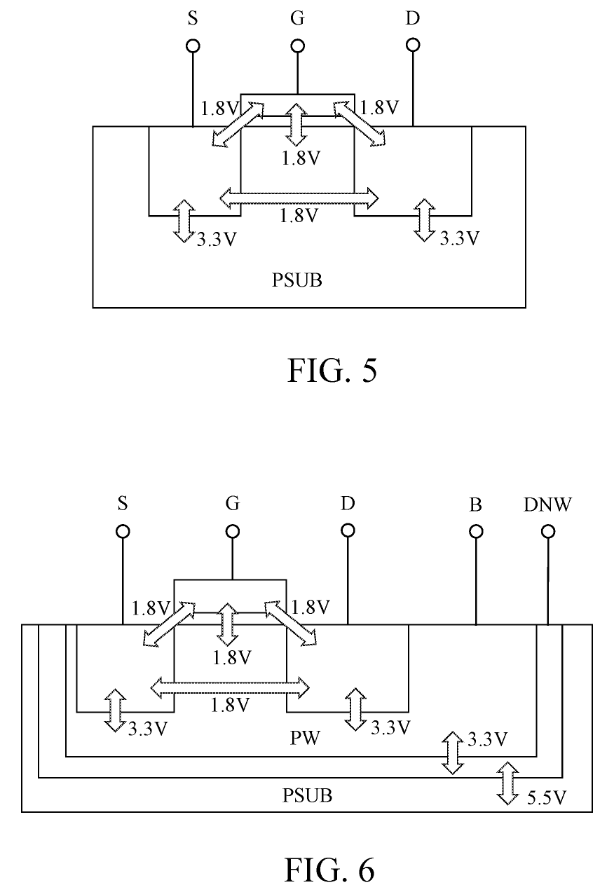

Referring to FIG. 5, FIG. 5 is a schematic structural diagram of a third transistor N according to an embodiment of the disclosure. The third transistor N is an N-type MOS transistor, and includes a substrate PSUB and a gate G, a source S and a drain D located thereon. For ease of understanding, a description is provided by using a specific voltage value as an example herein, but the embodiments of the disclosure are not limited thereto. A withstand voltage between any two of the gate G, the source S and the drain D is only 1.8 V. A withstand voltage between the gate G and the substrate PSUB is only 1.8 V. A withstand voltage between the source S and the substrate PSUB and a withstand voltage between the drain D and the substrate PSUB are 3.3 V. In other words, when the substrate PSUB is grounded, an upper voltage limit of the gate G is 1.8 V, and upper voltage limits of the source S and the drain D are 3.3 V.

Referring to FIG. 6, FIG. 6 is a schematic structural diagram of a second transistor Nd according to an embodiment of the disclosure. The second transistor Nd is a DNW N-type MOS transistor, and includes a deep N well DNW in addition to the substrate PSUB, the gate G, the source S, and the drain D described above. The deep N well DNW isolates a P-type well PW (that is, a bulk B) on the substrate PSUB. The gate G, the source S, and the drain D are located on the P-type well PW. In this way, a voltage difference from exceeding a withstand voltage as a result of the gate G and the drain D being adjacent to the substrate PSUB can be avoided. For ease of understanding, a description is provided by using a specific voltage value as an example herein, but the embodiments of the disclosure are not limited thereto. A withstand voltage between any two of the gate G, the source S and the drain D is only 1.8 V. A withstand voltage between the gate G and the P-type well PW is only 1.8 V. A withstand voltage between the source S and the P-type well PW, a withstand voltage between the drain D and the P-type well PW, and a withstand voltage between the deep N well DNW and the P-type well PW are 3.3 V. A withstand voltage between the deep N well DNW and the substrate PSUB may reach 5.5 V. Herein, the deep N well DNW is coupled to a high potential (for example, 5.5 V), and the substrate PSUB is grounded, to ensure that the deep N well DNW is maintained reversely biased, thereby avoiding a parasitic effect, and reducing leakage currents. The bulk B is coupled to the source S to reduce a body effect, and avoid effect of a turn-on capability of the second transistor Nd. In addition, since the bulk B is coupled to the source S, an allowable voltage range of the source S is equal to an allowable voltage range of the bulk B (2.2 V to 5.5 V). Compared with the example of FIG. 5, the source S may be enabled to be connected to a higher voltage by using the DNW N-type MOS transistor. Accordingly, upper voltage limits of the gate G and the drain D may be increased. A function of the DNW N-type MOS transistor in the switch circuit 100 operating beyond a component withstand voltage condition is described in detail below.

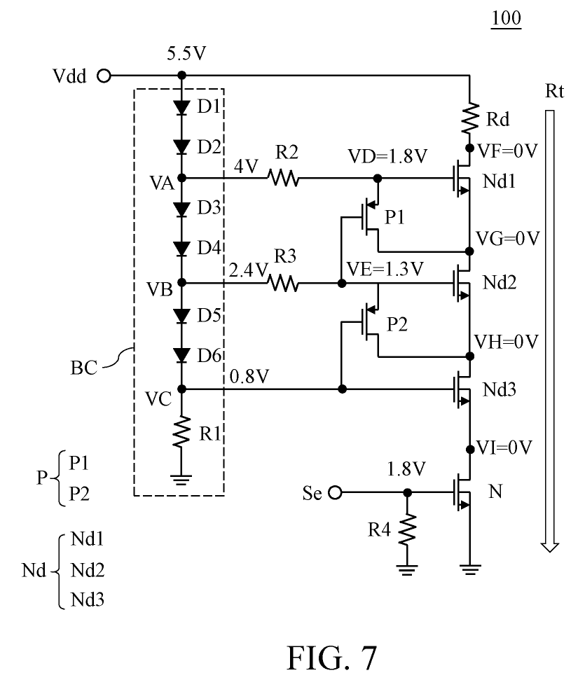

Referring FIG. 7, FIG. 7 is a schematic diagram of turning on a switch path Rt according to an embodiment of the disclosure. For ease of understanding, a description is provided by using a specific voltage value as an example herein, but the embodiments of the disclosure are not limited thereto. When a control signal Se is 1.8 V, a third transistor N is turned on, so that a voltage of a node VI between the third transistor N and a second transistor Nd3 is 0 V. If a voltage of a voltage source Vdd is 5.5 V, and a voltage across each of diodes D1 to D6 is 0.8 V, a voltage of a voltage drop node VA is 4 V, a voltage of a voltage drop node VB is 2.4 V, and a voltage of a voltage drop node VC is 0.8 V. A gate-source voltage (0.8 V minus 0 V) of the second transistor Nd3 is greater than a threshold voltage thereof (it is assumed that the threshold voltage is 0.2 V), thereby turning on the second transistor Nd3. Therefore, a voltage of a node VH between the second transistors Nd2 and Nd3 is 0 V. When the voltage of the node VH is 0 V, a small current flows from the voltage drop node VB to a node VE (which is located between a resistor R3 and a second gate of the second transistor Nd2) through the resistor R3, to forcibly pull low a voltage of the node VE to 1.3 V (which is equal to the voltage of the voltage drop node VC of 0.8 V plus a threshold voltage of the first transistor P2 of 0.5 V). In this way, a gate-source voltage (1.3 V minus 0 V) of the second transistor Nd2 is greater than a threshold voltage thereof (it is assumed that the threshold voltage is 0.2 V), thereby turning on the second transistor Nd2. Therefore, a voltage of a node VG between the second transistors Nd1 and Nd2 is 0 V. Similarly, when the voltage of the node VG is 0 V, a small current flows from the voltage drop node VA to a node VD (which is located between a resistor R2 and the second gate of the second transistor Nd1) through the resistor R2, to forcibly pull low a voltage of the node VD to 1.8 V (which is equal to the voltage of the voltage drop node VE of 1.3 V plus a threshold voltage of the first transistor P1 of 0.5 V). In this way, a gate-source voltage (1.8 V minus 0 V) of the second transistor Nd1 is greater than a threshold voltage thereof (it is assumed that the threshold voltage is 0.2 V), thereby turning on the second transistor Nd1. Therefore, a voltage of a node VF (which is located between a pull-down resistor Rd and a second drain of the second transistor Nd1) is 0 V, thereby turning on the switch path Rt.

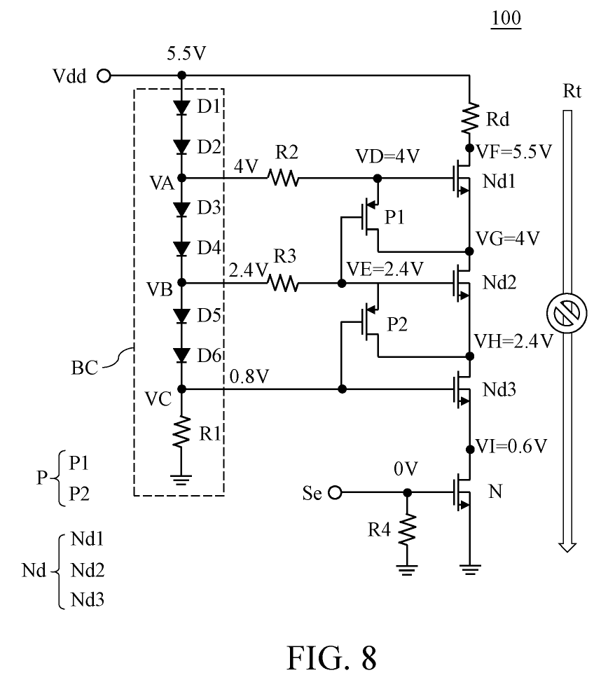

Referring FIG. 8, FIG. 8 is a schematic diagram of turning off a switch path Rt according to an embodiment of the disclosure. For ease of understanding, a description is provided by using a specific voltage value as an example herein, but the embodiments of the disclosure are not limited thereto. When a control signal Se is 0 V, a third transistor N is turned off, so that no current flows through the third transistor N. Therefore, no current flows through a resistor R2 and a resistor R3, so that a potential difference is not formed on two ends of each of the resistors R2 and R3. To be specific, a voltage of a node VD is the same as a voltage of a voltage drop node VA (4 V), and a voltage of a node VE is the same as a voltage of a voltage drop node VB (2.4 V). A gate-source voltage (2.4 V minus 0.8 V) of a first transistor P2 is greater than a threshold voltage thereof (0.5 V), thereby turning on the first transistor P2. Therefore, a voltage of a node VH is equal to the voltage of the node VE (2.4 V). In this way, a gate-source voltage (2.4 V minus 2.4 V) of a second transistor Nd2 is less than a threshold voltage thereof (it is assumed that the threshold voltage is 0.2 V), thereby turning off the second transistor Nd2. Similarly, a gate-source voltage (4 V minus 2.4 V) of a first transistor P1 is greater than a threshold voltage thereof (0.5 V), thereby turning on the first transistor P1. Therefore, a voltage of a node VG is equal to the voltage of the node VD (4 V). In this way, a gate-source voltage (4 V minus 4 V) of a second transistor Nd1 is less than its threshold voltage (it is assumed that the threshold voltage is 0.2 V), thereby turning off the second transistor Nd1. No current exists in a second gate of a second transistor Nd3, so that the second transistor Nd3 is turned off. In this way, a voltage drop of a threshold voltage (0.2 V) exists between a node VI and the voltage drop node VC, and therefore a voltage of the node VI is 0.6 V. The second transistors Nd1 to Nd3 and the third transistor N on the switch path Rt are all turned off, and no current flows through a pull-down resistor Rd. Therefore, a voltage of a node VF is equal to a voltage of 5.5 V of a voltage source Vdd.

It may be learned from FIG. 7 and FIG. 8 that voltage differences between the gates, the sources, and the drains of the first transistors P1 and P2, the second transistors Nd1 to Nd3, and the third transistor N all satisfy the withstand voltage conditions shown in FIG. 5 and FIG. 6. It is worth mentioning that, since the second transistors Nd1 to Nd3 adopts DNW N-type MOS transistors, the second transistors still satisfy the withstand voltage condition under a higher voltage environment (the nodes VF, VG and VH as shown in FIG. 8).

Although the above embodiments are described by using the three voltage drop nodes VA to VC and the corresponding second transistors Nd1 to Nd3 (which constitute a three-layer switch mechanism) as an example, a quantity of layers may be flexibly adjusted, and depends on parameters such as a voltage and a component withstand voltage condition of the actual voltage source Vdd.

According to the switch circuits 100 operating beyond a component withstand voltage condition in some embodiments of the disclosure, the bias components of the bias circuit BC are adopted to layer in series, so that the component of each layer can perform switch control in a withstand voltage range thereof, to achieve the switch circuit operating at an operating voltage beyond the component withstand voltage condition. In addition, whether a current flows through the voltage drop node VC, the node VD, and the node VE may be determined through whether the third transistor N is turned on, so that the voltage drop node VC, the node VD, and the node VE are automatically biased to a proper voltage. Therefore, the switch circuit can be controlled through only a need of feeding a control signal. Possible situations may be avoided, such as a temporary component overvoltage as a result of a delay of another control signal fed to the voltage drop node VC, the node VD, and/or the node VE.

What is claimed is:

1. A switch circuit operating beyond a component withstand voltage condition, comprising:
a bias circuit, comprising a plurality of bias components connected in series with each other, and coupled to a voltage source, to form a plurality of voltage drop nodes through the bias components;
at least one first transistor;
a plurality of second transistors, connected in series with each other, coupled to the voltage source, and coupled to the voltage drop nodes in a one-to-one manner, wherein the first transistor is arranged between any two adjacent second transistors among the second transistors; and
a third transistor, connected in series with the second transistors to form a switch path, and located on a low voltage side of the second transistors, wherein
when the third transistor receives a control signal and is turned on, the first transistors are turned off, and the second transistors are turned on, thereby turning on the switch path.; and
when the third transistor receives the control signal and is turned off, the first transistors are turned on, and the second transistors are turned off, thereby turning off the switch path.

2. The switch circuit operating beyond a component withstand voltage condition according to claim 1, wherein each of the first transistors is a P-type metal-oxide-semiconductor (MOS) transistor, and has a first gate, a first source, and a first drain.

3. The switch circuit operating beyond a component withstand voltage condition according to claim 1, wherein each of the second transistors is a deep N well (DNW) N-type MOS transistor, and has a second gate, a second source, and a second drain, and the second gate is coupled to the corresponding voltage drop node.

4. The switch circuit operating beyond a component withstand voltage condition according to claim 3, wherein each first transistor is a P-type MOS transistor, and has a first gate, a first source, and a first drain, the second gate and the second drain of the second transistor adjacent to the low voltage side to which each first transistor is coupled are respectively coupled to the first gate and the first drain of the first transistor, and the second gate of the second transistor away from the low voltage side to which each first transistor is coupled is coupled to the first source of the first transistor.

5. The switch circuit operating beyond a component withstand voltage condition according to claim 4, wherein in any two adjacent second transistors among the second transistors, the second drain of the second transistor adjacent to the low voltage side is coupled to the second source of the second transistor away from the low voltage side.

6. The switch circuit operating beyond a component withstand voltage condition according to claim 5, wherein the third transistor is an N-type MOS transistor, and has a third gate, a third source, and a third drain, the third gate is configured to receive the control signal, the third source is grounded, and the third drain is coupled to the second source of the second transistor to which the third transistor is coupled.

7. The switch circuit operating beyond a component withstand voltage condition according to claim 1, wherein the switch path further comprises a pull-down resistor, coupled between the voltage source and a high voltage side of the second transistors.

8. The switch circuit operating beyond a component withstand voltage condition according to claim 1, wherein the bias components are a plurality of resistors connected in series.

9. The switch circuit operating beyond a component withstand voltage condition according to claim 1, wherein the bias components are a plurality of diodes connected in series, and the diodes are forward biased with the voltage source.

10. The switch circuit operating beyond a component withstand voltage condition according to claim 1, wherein the bias components are a plurality of fourth transistors connected in series, each of the fourth transistors is an N-type MOS transistor, and has a fourth gate, a fourth source, and a fourth drain, and the fourth drain is coupled to the fourth gate, and is coupled to the fourth source of the fourth transistor adjacent to the fourth drain.
